(19) United States
(12) Patent Application Publication
(10) Pub. No.: US 2012/0308042 A1
(43) Pub. Date: Dec. 6, 2012

(54) Subwoofer Volume Level Control

(75) Inventor: Stanley K.P. Victor, Grosse Pointe Park, MI (US)

(73) Assignee: VISTEON GLOBAL TECHNOLOGIES, INC., Van Buren Township, MI (US)

(21) Appl. No.: 13/150,280

(22) Filed: Jun. 1, 2011

(51) Int. Cl. H03G 5/00

(52) U.S. Cl. 381/98

(57) ABSTRACT

An automatic adjustment of subwoofer volume levels relative to the main audio system volume and more specifically, to an improved algorithm control method for sub varying volume which allows adjustment of only the low frequency tones from the subwoofer relative to the main system volume.

### BACKGROUND OF THE INVENTION

1. Technical Field

The present invention generally relates to an automatic adjustment of subwoofer volume levels relative to the main audio system volume and more specifically, to an improved algorithm control method for varying subwoofer volume which allows adjustment of only the low frequency tones from the subwoofer relative to the main system volume.

2. Discussion

Traditional acoustic or audio systems are provided with a bass and a treble adjustment, each which allows manipulation of the sound to achieve the desired tones. As audio systems progressed, and in particular, entertainment systems for vehicles, many of these systems included a separate subwoofer speaker for reproducing low frequency tones. As such, many of these systems also included a separate adjustment for the subwoofer such that the listener may increase the subwoofer output level or decrease the subwoofer output level relative to the main system volume.

One problem with these adjustments was the amount of variance applied by the adjustment of the subwoofer volume was static or a linear relationship relative to the main system volume levels. For example, if an operator increases the gain of the subwoofer by +5, the subwoofer may have the desired relative output level to the main system volume at the main system volume level where the user adjusted the subwoofer volume. However, as the main system level is decreased relative to the volume where the adjustment was made, the subwoofer volume gain may be too high and may overpower the main system volume level thereby producing a higher volume of low frequency tones than desired in comparison to the mid and high frequency tones in the main system volume. Likewise, as the system volume is increased, the main system volume may overpower the subwoofer and as the volume nears the maximum, the subwoofer may reach an overdriven mode before the main system volume is maxed due to the added gain, causing undesirable sounds from the subwoofer. Such linear adjustment of the subwoofer output level relative to the main system volume is not desirable. As such, the desired sound quality and perceived audio difference will not be retained through the full range of audio output levels by the main system volume with the low frequency tones overpowering the mid and high frequency tones at low main system volumes and being underpowered at high main system volumes, and in some cases causing the subwoofer to be overdriven.

More specifically, the issue with using a fixed gain on the subwoofer output level is that the audio sound quality will likely suffer as the system output level increases because as the upper volume levels of the system are reached, the subwoofer transducer will go into an operation mode that has significant amount of distortion due to mechanical and electrical constraints. For example, if the gain on the subwoofer has been increased around the midpoint volume level of the main system volume, as the main system volume level is increased, the subwoofer may be driven past its desirable operating range.

Additional problems with fixed gain level controls for subwoofer is that many times the subwoofer gain level cannot be easily changed by the user because the control is physically located on the powered subwoofer unit. For example, on many home entertainment systems, the powered subwoofer is placed in a hard-to-reach area and the only control knob for the powered subwoofer output level is physically on the subwoofer, many times on the rear or underside of the subwoofer.

Another issue with current subwoofer technology is that the low frequency content is combined together with all other audio content, or recombined with other audio content before it is sent to the subwoofer unit. Therefore, manipulation of the mid and high frequency tones as well as any other manipulation of the sound before being output by the speakers may affect the audio quality provided by the subwoofer.

### SUMMARY OF THE INVENTION

The present invention generally relates to an automatic adjustment of subwoofer volume levels relative to the main audio system volume and more specifically, to an improved algorithm control method for varying subwoofer volume which allows adjustment of only the low frequency tones from the subwoofer relative to the main system volume.

The method for processing an audio signal generally includes, receiving an audio signal, extracting a low frequency signal from said received audio signal, applying an algorithmic gain adjustment to said low frequency signal to create an adjusted low frequency signal, and outputting said adjusted low frequency signal to a subwoofer. The adjusted low frequency signal is not recombined with said audio signal before being output to said subwoofer, and the step of extracting a low frequency signal from said received audio signal also includes the step of extracting at least one of a high frequency signal and a mid-frequency signal and wherein said low frequency signal is not combined with said at least one high frequency signal and mid-frequency signal.

### BRIEF DESCRIPTION OF THE DRAWINGS

Further details, features, and advantages of the invention will become readily apparent after review of the following description of examples of embodiment, with reference to the associated drawings. The drawings show

FIG. 1 is a schematic diagram of a prior art traditional signal path for a powered subwoofer;

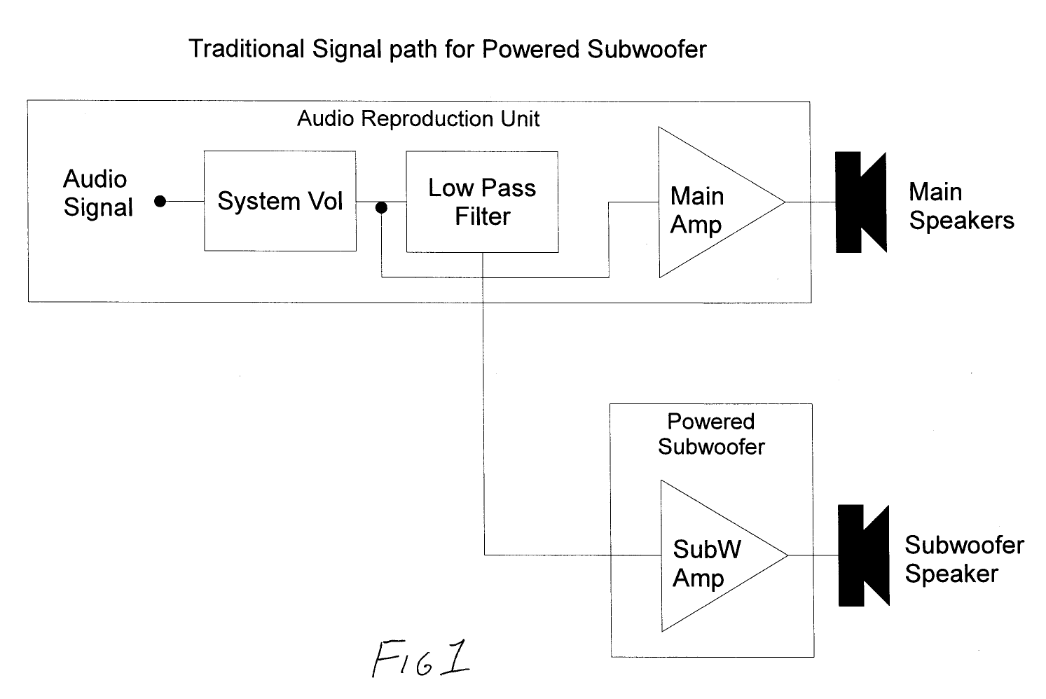

FIG. 2 is a schematic diagram of an algorithmic software control signal path for a powered subwoofer using the present invention;

FIG. 3 is a schematic diagram of the present invention; and

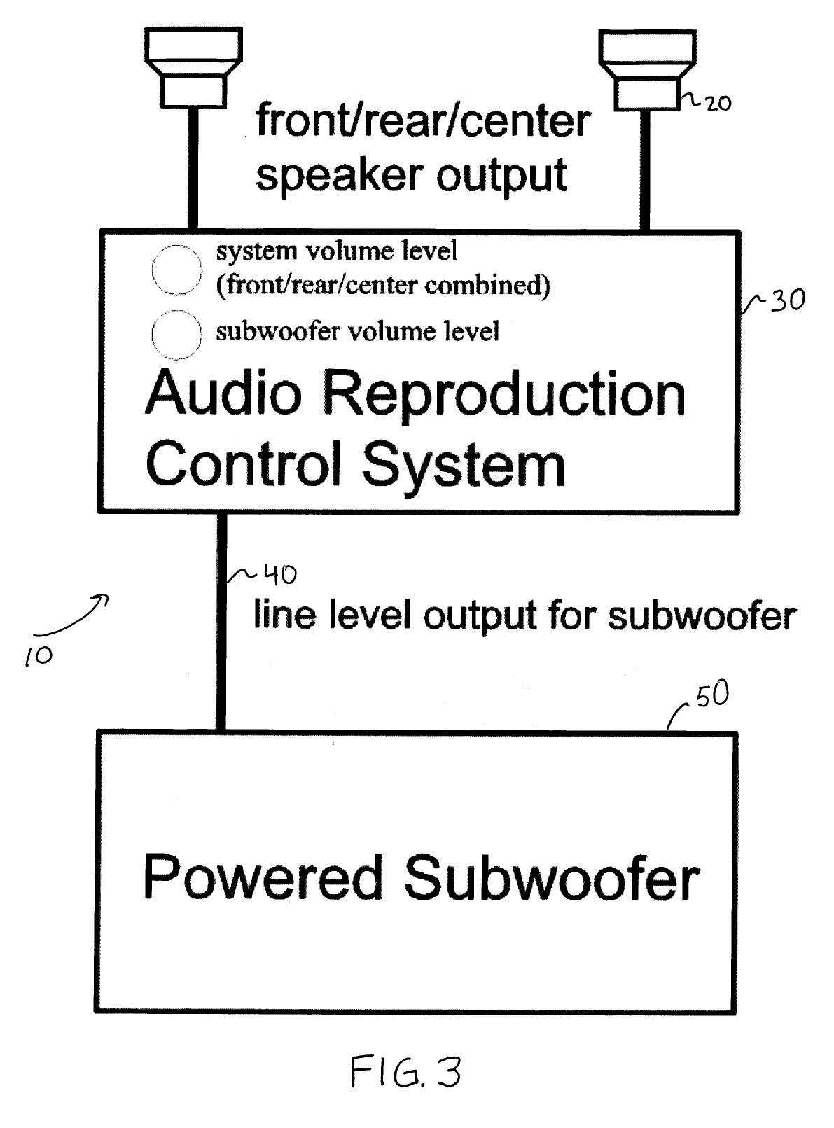

FIG. 4 is a graph showing output levels of a subwoofer using the present invention relative to the main system volume level.

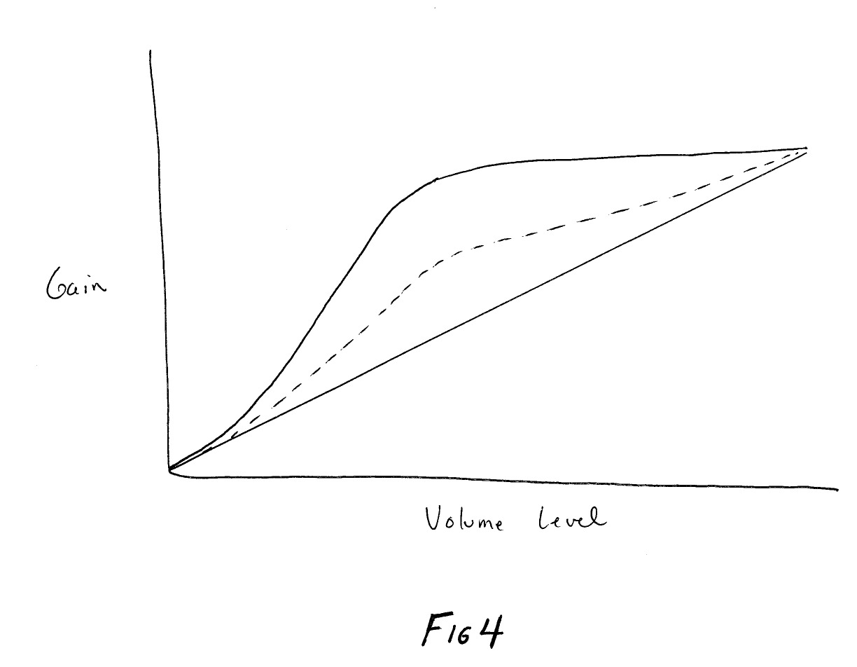

### DETAILED DESCRIPTION OF THE PREFERRED EMBODIMENT

The present invention generally includes an audio or entertainment system 10 having an audio reproduction control system 30, speakers 20, a powered subwoofer 50 and a line level output 40 between the audio reproduction control system 30 and the powered subwoofer 50. The speakers 10 and powered subwoofer 50 may be any speakers and subwoofer of any size, shape and configuration capable of reproducing sound received from the audio reproduction control system 30. The audio reproduction control system 30 generally uses an algorithm to adjust the subwoofer volume level output to subwoofer 50 relative to the system volume level which is output generally to the speakers 20. The present invention is also generally directed to a method for processing the audio signal to apply an algorithm non-linear adjustment to the subwoofer audio output to maximize the desired adjusted subwoofer sound level for the user while preventing the subwoofer from overdriven at high master volume levels.

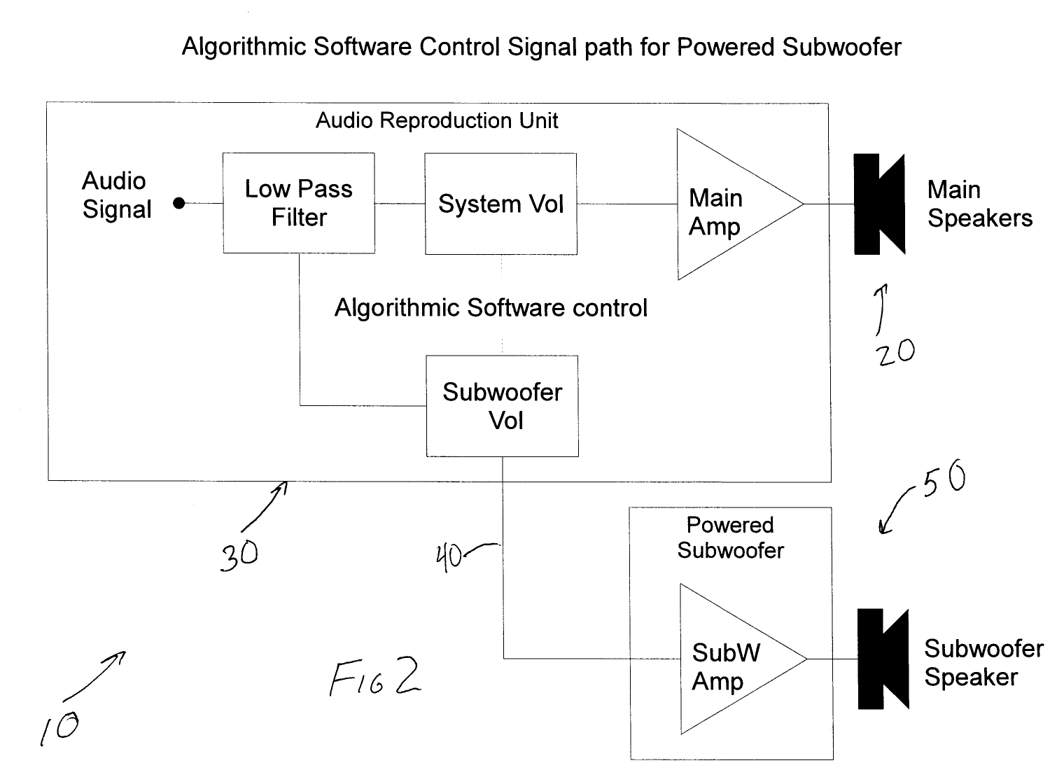

The audio system, more specifically, the audio reproduction system 30 generally has a master system volume level and a subwoofer volume level. Traditionally, as the master system volume level increases, the subwoofer volume level increases in a linear manner. In the present invention, when the algorithm adjustment is applied, the volume level of the subwoofer as illustrated in FIG. 2 is non-linear. As also illustrated in FIG. 2, the amount of algorithm adjustment may vary depending upon the desired adjustment of the subwoofer volume level such that a smaller increase in gain is closer in a resemblance to a linear adjustment than a large increase as illustrated in FIG. 2. As also illustrated in FIG. 2, the algorithmic adjustment also provides an upper limit to the subwoofer volume level such that the master volume level and subwoofer volume level never combine to an amount that causes the subwoofer 50 to be overdriven thereby decreasing the sound quality provided by the subwoofer 50.

The method of the present invention is primarily directed to the steps of receiving an audio signal, extracting a low frequency signal from the received audio signal, applying an algorithmic gain adjustment to the extracted low frequency signal to create an adjusted low frequency signal and outputting the adjusted low frequency signal to a subwoofer. It should be clear that the algorithmic gain adjustment could be either positive or negative specifically that a positive increase in gain increases the volume output of the subwoofer while a negative increase in gain decreases the volume of the subwoofer. Whether the algorithmic adjustment is either positive or negative, the adjustment is non-linear.

The received audio signal of any audio signal typically received an output by an audio system such as a vehicle entertainment center. For example, the received audio signal can be related to the signal from a CD player, DVD player, a receiver, a mass storage device such as a cell phone or MP3 player, or any other device capable of producing an audio signal. As referred to in this invention, the received audio signal is generally the audio signal before being amplified and output to the speakers 20 or subwoofer 50. The received audio signal generally is a full spectrum signal including low frequency signals, mid range frequency signals and high frequency range frequency signals.

The audio reproduction control system 30 will then extract a low frequency signal from the received audio signal. This extraction of the low frequency signal may occur after blending of the audio signal but before amplification of the signal. However, it is believed to be preferable to extract the low frequency signal before any blending adjustments are applied to the audio signal. The present invention may use any known method for extracting the low frequency signal from the audio signal such as a low frequency filter. The above-mentioned step of blending the audio signal may include adjustments to the bass, treble or other applied adjustments.

It is important to note that the low frequency signal extracted and then adjusted is not combined with the audio signal again before being output to the subwoofer. Keeping the extracted low frequency signal and in particularly, the adjusted low frequency signal separate, allows a cleaner output of to the adjusted low frequency signal to the powered subwoofer 50. In the prior art, the low frequency signals are blended with the main audio signal and then amplified and then re-extracted before being sent to the powered subwoofer. This amplification was done to allow the subwoofer to adjust linearly with the main system volume level. However, in the present invention, the audio reproduction control system takes into account the desired master volume level and uses that level on the subwoofer output as a base level and then adjusts that level with the step of applying an algorithmic gain adjustment to the low frequency signal. Therefore, the master system volume level is always the base level of the subwoofer also even though the master volume level may not directly control or interact with the line level output 40 to the subwoofer 50.

As discussed above, in the step of applying the algorithmic gain adjustment to the low frequency signal, the adjustment applied is non-linear. The manufacturer of the system is expected to enter the maximum level at which a subwoofer may be driven such that the master volume level and the applied adjustment do not exceed the capabilities of the subwoofer. As the algorithm is set for a particular set of speakers and subwoofer, if the user adjusts the subwoofer +5 at a 25% master volume level as illustrated in FIG. 2, when the master volume level reaches 50% of maximum, it is expected that the amount of additional adjustment applied to the subwoofer is increased. As the master level volume is increased, at some point the adjusted subwoofer level and master volume level in combination reach the maximum capabilities of the subwoofer. Therefore, while the gain may be +5 at a 25% master volume level and +9 at a 50% volume level, it may be only +3 at an 80% volume level, and 0 at 100% volume level. Of course, these amounts are only exemplary and may depend on the system components in the system, settings and desired audio input as well as the amount of gain selected by the user. In addition, the algorithm may change depending upon the configuration of space in which the entertainment center is located as well the components of the entertainment center.

The exact algorithm may be selected by the manufacturer of the audio system such as selected for a particular vehicle entertainment system to provide the highest quality sound output for differing consumer tastes in a particular vehicle. It is also possible that the audio reproduction control system 30 may be set up such that the user may select different algorithms, changing the amount of subwoofer volume at set master volume levels without having the user change the gain individually on the subwoofer. For example, if a user is listening to a genre that needs a particular amount of bass, one algorithm may be used and for a different genre of music, another algorithm with less bass may be used. The algorithm may be set similar to that of an equalization where the equalizer has preset settings, maximizing the sound output quality for the particular genre.

Therefore, the present invention moves the subwoofer gain control from the actual subwoofer assembly to the audio reproduction control system and improves audio quality over the full range of system audio levels while providing high audio output quality as well as ease of use in setting the subwoofer gain level. The algorithm is particularly configured to ensure that the subwoofer does not enter an operational mode that induces distortion in the audio output. The algorithm is also selected or developed to keep the subwoofer at optimum performance levels throughout the volume range of the master volume level. The algorithm also allows the listener to maintain desired or perceived gain level differences between a system and a subwoofer across the full system volume range until the subwoofer is limited to prevent it from entering a distortion mode, or overpowering the main system volume.

What is claimed is:

1. A method for processing an audio signal, comprising:
receiving an audio signal;
extracting a low frequency signal from said received audio signal;
applying an algorithmic gain adjustment to said low frequency signal to create an adjusted low frequency signal; and
outputting said adjusted low frequency signal to a subwoofer.

2. The method of claim 1 wherein said adjusted low frequency signal is not recombined with said audio signal before being output to said subwoofer.

3. The method of claim 1 wherein said step of extracting a low frequency signal from said received audio signal also includes the step of extracting at least one of a high frequency signal and a mid-frequency signal and wherein said low frequency signal is not combined with said at least one high frequency signal and mid-frequency signal.

4. The method of claim 1 wherein said at least one high frequency signal and mid frequency signal are amplified by an amplifier before being output to at least one speaker and wherein said low frequency signal is not amplified by said amplifier.

5. The method of claim 3 wherein said step of applying an algorithmic gain adjustment to said low frequency signal includes the step of applying a non-linear adjustment to said low frequency signal relative to a master system volume.

6. The method of claim 5 wherein said step of applying said non-linear adjustment includes the steps of applying a set gain at a mid volume level of said master system volume and a reduced set gain at the low volume levels of said master system volume.

7. The method of claim 1 wherein said step of applying an algorithmic gain adjustment includes the step of limiting the gain adjustment.

8. The method of claim 7 wherein said step of limiting the gain adjustment includes the step of adjusting the limit of the gain adjustment relative to a master system volume.

9. The method of claim 8 wherein said step of limiting the gain adjustment includes an upper limit output level to said subwoofer.

10. The method of claim 1 wherein said step of extracting said low frequency signal occurs before any gain adjustment or equalization adjustments to the audio signal.

11. The method of claim 1 wherein said step of extracting said low frequency signal occurs before any other audio adjustments to said audio signal.

12. The method of claim 1 further including the step of blending the audio signal after extracting said low frequency signal.

13. The method of claim 1 wherein said step of applying an algorithmic adjustment includes setting the low frequency signal to zero when a master system volume level is set to zero.

14. The method of claim 1 wherein said step of applying an algorithmic adjustment creates a variance of the subwoofer level from a main system volume level and wherein the amount of said variance is proportional to the amount of gain adjustment.

15. The method of claim 1 further including the step of setting a gain amount for said low frequency signal wherein as said gain increases, the amount of variance of the algorithmic adjustment from a linear deviation increases.

16. The method of claim 1 wherein said step of extracting the low frequency signal occurs after a step of blending the audio signal and before a step of amplifying the audio signal.
